(19) United States
(12) Patent Application Publication
(10) Pub. No.: US 2012/0266673 A1
(43) Pub. Date: Oct. 25, 2012

(54) INERTIAL SENSOR AND METHOD OF MANUFACTURING THE SAME

(75) Inventors: Hyun Kee Lee, Gyunggi-do (KR); Heung Woo Park, Gyunggi-do (KR); Nam Su Park, Gyunggi-do (KR); Yeong Gyu Lee, Gyunggi-do (KR); Sung Min Cho, Gyunggi-do (KR)

(73) Assignee: SAMSUNG ELECTRO-MECHANICS CO., LTD., Gyunggi-do (KR)

(21) Appl. No.: 13/185,660

(22) Filed: Jul. 19, 2011

(30) Foreign Application Priority Data
Apr. 22, 2011 (KR) 1020110038067

(51) Int. Cl. G01P 15/08; H01L 21/02

(52) U.S. Cl. 73/514.16; 438/50; 257/E21.002

(57) ABSTRACT

Disclosed herein is an inertial sensor. The inertial sensor includes a sensor unit including a flexible substrate part on which a driving electrode and a sensing electrode are formed, a mass displaceably mounted on the flexible substrate part, and a support body coupled with the flexible substrate part in order to support the mass in a floated state and made of silicon; and a lower cap covering a bottom portion of the mass and made of silicon, wherein the lower cap and the sensor unit are coupled by a silicon direct bonding method, whereby the inertial sensor and the method of manufacturing the same may be obtained to improve the convenience in manufacturing and the reliability of the sensor by bonding the sensor unit and the lower cap by the silicon direct bonding method.

### CROSS REFERENCE TO RELATED APPLICATION

This application claims the benefit of Korean Patent Application No. 10-2011-0038067, filed on Apr. 22, 2011, entitled “Inertial Sensor and Manufacturing Method of the Same” which is hereby incorporated by reference in its entirety into this application.

### BACKGROUND OF THE INVENTION

1. Technical Field

The present invention relates to an inertial sensor and a method of manufacturing the same.

2. Description of the Related Art

An inertial sensor measuring a physical amount of acceleration and/or angular velocity has been widely used while being mounted in a motion remote controller for screen conversion of a mobile phone, a game, and a digital TV, a remote controller of a game machine, and a sensor module for sensing hand shaking and sensing a position and an angle of motion, or the like.

Further, the inertial sensor senses acceleration or angular velocity for a motion of a target to be sensed and converts the sensed acceleration or the angular velocity into an electrical signal. As a result, it is possible to implement a motion interface by using the motion of a user as an input unit at the time of operating devices. In addition, the inertial sensor has a very wide range such that it can be used for a navigation and control sensor of an airplane and a vehicle, in addition to a motion sensor such as home appliances, or the like.

In addition, as the inertial sensor is used for a portable PDA, a digital camera, or a mobile phone, or the like, a need exists for a technology capable of implementing a compact and light inertial sensor with various functions. As a result, a technology of a micro-sensor module has been demanded.

Further, the inexpensive and micro-inertial sensor for home appliances and personal digital assistants has mainly used a capacitive type and a type using a piezo-electric element. A driving unit of the inertial sensor may be sorted into a piezo-electric type and a capacitive type and a sensing unit may be sorted into a piezo-electric type, a capacitive type, and a piezoresistive type.

In detail, the piezo-electric uses a reverse piezo-electric effect that deforms a piezo-electric body when AC voltage is applied to the piezo-electric body and the piezo-electric sensing type uses a direct piezo-electric effect that generates charges when stress is applied to the piezo-electric body. For example, U.S. Pat. No. 5,646,346 discloses an angular sensor that uses a piezo-electric element formed on a plate-shaped flexible part as a driving unit and a sensing unit.

Unlike the piezo-electric driving type and the piezo-electric sensing type, the capacitive driving type vibrates a mass by electrostatic force generated when AC voltage is applied between two electrodes disposed to be opposite to each other at a close range and the capacitive sensing type is a method of detecting voltage that is generated by a relative displacement between two electrodes. For example, U.S. Pat. No. 6,003,371 discloses an angular velocity sensor that uses as a driving unit and a sensing unit a capacitive element configured of an electrode formed on a mass or a plate-shaped flexible part and a fixing electrode.

In addition, a method of increasing an area of an electrode by forming a comb-shaped electrode in order to increase sensitivity has been widely used. The piezoresistive sensing type uses a piezoresistive that uses a piezoresistive effect changing a resistive value according to deformation. Japanese Registration Patent No. 3171970 discloses as a sensing unit sensing a deformation of a flexible part an acceleration sensor that uses piezoresistive elements formed on a plurality of flexible parts having a beam shape.

Further, in the case of the driving or sensing according to the capacitive type, a method of controlling Δf by changing a resonance frequency of a driving mode or a sensing mode corresponding to and electrostatic force generated by applying DC bias voltage to a capacitive element is known in a plurality of documents, in addition to a reference document entitled “A Micromachined Vibrating Rate Gyroscope with Independent Beams for the Drive and Detection Modes”. However, since the method requires high voltage and increases power consumption, the method is not suitable to apply to a mobile device.

Further, in the case of the driving or sensing according to the piezo-electric type, the angular velocity sensor may become more sensitive due to a high electro mechanical coupling coefficient of the piezo-electric effect.

Meanwhile, the piezo-electric element for implementing the inertial sensor may be deformed when being applied with voltage, while the piezo-electric element generates charges when being applied with force from the outside, such that the piezo-electric element may be widely used for various types of actuators, sensors, or the like.

Further, a material of the piezo-electric element may be made of various materials such as Aln, ZnO, Quartz, or the like, but a PZT having a large piezo-electric constant has been mainly used for various fields. In order to improve characteristics of the PZT, the PZT is subjected to a poling process prior to an operation after manufacturing and the piezo- [symbol] subjected to a poling process prior to an operation after manufacturing and the piezo-electric characteristics are improved during the application of temperature and voltage.

The type using the piezo-electric element may be implemented by normal-pressure packaging without performing vacuum packaging, when comparing with the capacitive type. Further, the inexpensive and micro-inertial sensor according to the piezo-electric type is manufactured by a bulk micro-machining technology of a silicon structure and includes a circular plate spring, wherein a middle of the plate spring is provided with a cylindrical silicon mass and the mass moves in an up and down direction or left and right/front and rear directions or a combined direction thereof according to the application of the driving voltage.

As described above, the inexpensive and micro-inertial sensor according to the piezo-electric type uses a method of manufacturing a device wafer, that is, a sensor unit by forming an electrode pattern, a mass, and a support body on a top portion thereof, manufacturing a lower cap coupled with a bottom portion of the sensor unit so as to protect the mass of the sensor unit, applying an adhesive material, a polymer to the lower cap, and coupling the sensor unit with the lower cap, in the methods of manufacturing thereof.

According to the above manufacturing method, since the sensor unit and the lower cap are bonded by the polymer, defects, such as flatness error may occur at the time of bonding using the polymer and a bonding portion may be damaged due to temperature and external factors even after the bonding and since the cavity is formed at the lower cap, the polymer patterning process may be complicated and the manufacturing costs may be increased due to the expensive polymer.

### SUMMARY OF THE INVENTION

The present invention has been made in an effort to provide an inertial sensor and a method of manufacturing the same capable of improving convenience in manufacturing and reliability of a sensor by coupling a sensor unit with a lower cap of an inertial sensor by a silicon direct bonding method.

According to a preferred embodiment of the present invention, there is provided an inertial sensor, including: a sensor unit including a flexible substrate part on which a driving electrode and a sensing electrode are formed, a mass displaceably mounted on the flexible substrate part, and a support body coupled with the flexible substrate part in order to support the mass in a floated state and made of silicon; and a lower cap covering a bottom portion of the mass and made of silicon, wherein the lower cap and the sensor unit are coupled by a silicon direct bonding method.

The silicon direct bonding method may remove pollutants on a surface of a wafer, perform hydrophilic processing thereon, initially bond the sensor unit and the lower cap by pressing, bond the sensor unit and the lower cap by using a bonding agent and pressing, and finally bond the sensor unit and the lower cap by high-temperature heat treatment.

The inertial sensor may further include an upper cap covering a top portion of the flexible substrate part.

The upper cap may be made of silicon, the flexible substrate part may be formed of a silicon on insulator (SOI) wafer, and the upper cap and the flexible substrate part may be coupled by the silicon direct bonding method.

According to another preferred embodiment of the present invention, there is provided a method of manufacturing an inertial sensor, the method including: a sensor unit forming step forming a mass and a support body by etching a silicon on insulator (SOI) wafer; a lower cap forming step providing a lower cap coupled with the support body so as to cover the mass of the SOI wafer; a silicon direct bonding step coupling the lower cap with the SOI wafer; a silicon direct bonding step coupling the lower cap with the support body of the SOI wafer; and an electrode pattern forming step forming an electrode pattern on the top surface of the SOI wafer.

The lower cap forming step may prepare a silicon wafer and form a cavity by etching the silicon wafer.

The silicon direct bonding method may remove pollutants on a surface of a wafer, perform hydrophilic processing thereon, initially bond the sensor unit and the lower cap by pressing, bond the sensor unit and the lower cap by using a bonding agent and pressing, and finally bond the sensor unit and the lower cap by high-temperature heat treatment.

A pressure applied during the initial bonding step may be 0.6 bar to 0.8 bar.

The hydrophilic processing step may be a plasma activation method.

The bonding step may perform pressing at 15° C. to 400° C. or less using a bonding agent.

The final bonding step may perform heat treatment at 1000° C. to 1300° C. using a furnace.

The final bonding step may include a holding step holding at normal temperature before high-temperature heat treatment.

The holding step may perform the holding for 24 hours to 48 hours.

The electrode pattern forming step may deposit an electrode material on a top surface of the device wafer and form a driving electrode pattern and a sensing electrode pattern by pattern formation.

### BRIEF DESCRIPTION OF THE DRAWINGS

FIG. 1 is a cross-sectional view schematically showing an inertial sensor according to a preferred embodiment of the present invention.

FIG. 2 is flow chart schematically showing a method of manufacturing an inertial sensor shown in FIG. 1.

FIG. 3 is a flow chart schematically showing a silicon direct bonding process in the method of manufacturing an inertial sensor according to the preferred embodiment of the present invention.

FIG. 4 is a cross-sectional view schematically showing the inertial sensor according to the preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it [symbol] components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

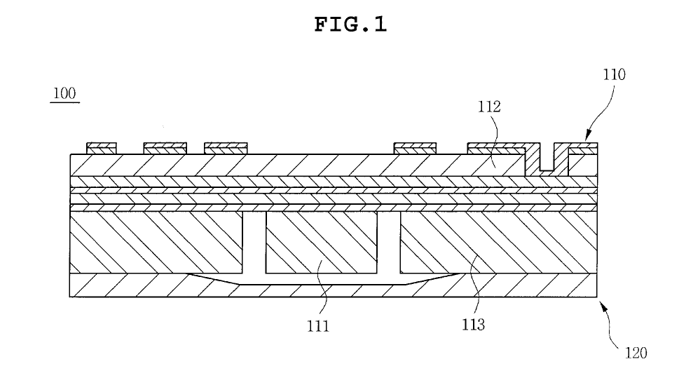

FIG. 1 is a cross-sectional view schematically showing an inertial sensor according to a preferred embodiment of the present invention. As shown, an inertial sensor 100 includes a sensor unit 110 and a lower cap 120. Herein, the sensor unit 110 includes a mass 111, a flexible substrate part 112, and a support body 113.

In more detail, the flexible substrate part 112 includes a flexible substrate, a piezo-electric material (PZT), and an electrode, wherein the flexible substrate is formed of a silicon single crystal substrate, that is, a silicon on insulator (SOI) wafer and is provided with a driving electrode and a sensing electrode by being deposited with the piezoelectric element and the electrode.

Meanwhile, the mass 111 is made of silicon and is displaceably located on a bottom portion of the flexible substrate part 112 and moves according to the application of voltage to the driving electrode of the flexible substrate part 112.

In addition, the support body 113 is formed of a silicon substrate and is coupled with the flexible substrate part 112 and supports the mass 111 so that the mass 111 may freely move in a floated state.

In addition, the lower cap 120 is to protect the mass 111 and is provided with cavity by etching a silicon wafer.

Further, the support body 113 and the lower cap 120 are coupled by a silicon direct bonding method.

Further, the silicon direct bonding method is implemented by a method of removes pollutants on a surface of a bonding target, a wafer, performing hydrophilic processing thereon, initially bonding the sensor unit and the lower cap by pressing, bonding the sensor unit and the lower cap by using a bonding agent and pressing, and finally bonding the sensor unit and the lower cap by high-temperature heat treatment. The description of the method of manufacturing an inertial sensor will be described in more detail below.

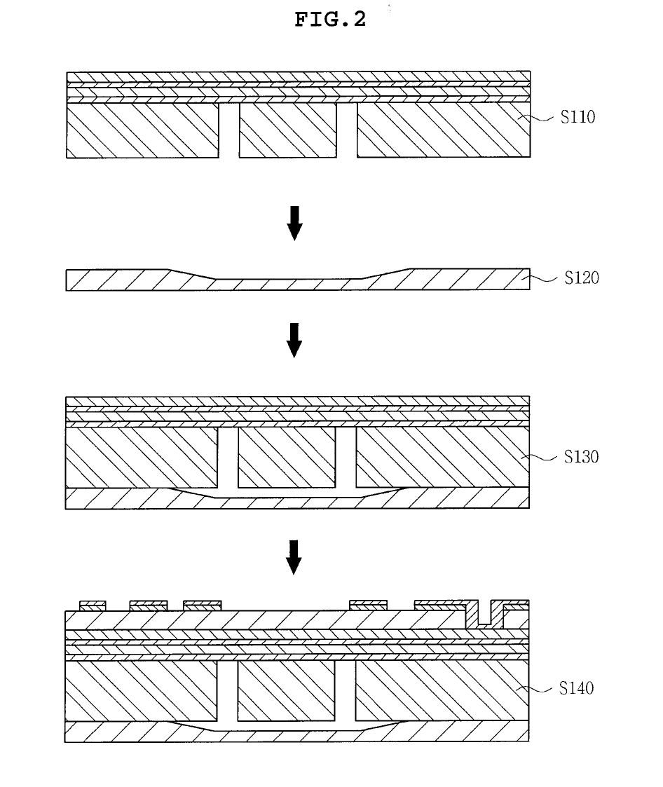

FIG. 2 is flow chart schematically showing a method of manufacturing an inertial sensor shown in FIG. 1. As shown, the method of manufacturing an inertial sensor includes a sensor unit forming process forming the mass and the support body by etching a silicon on insulator (SOI) wafer (S110), a lower cap forming process providing the lower cap coupled with the support body so as to cover the mass of the SOI wafer (S120), a silicon direct bonding process coupling the lower cap with the SOI wafer (S130), and an electrode pattern forming process forming the electrode pattern on the top surface of the SOI wafer (S140).

In more detail, the sensor forming step (S110) prepares the device wafer and forms the mass and the support body by etching the bottom portion of the wafer.

In addition, the lower cap forming step (S120) prepares the silicon wafer and forms the cavity by etching.

In addition, the electrode pattern forming step (S140) deposits the electrode material on the top surface of the device wafer and forms a driving electrode pattern and a sensing electrode pattern by the pattern formation.

Hereinafter, the silicon direct bonding step (S130) of the SOI wafer and the lower cap according to the exemplary embodiment of the present invention will be described in more detail.

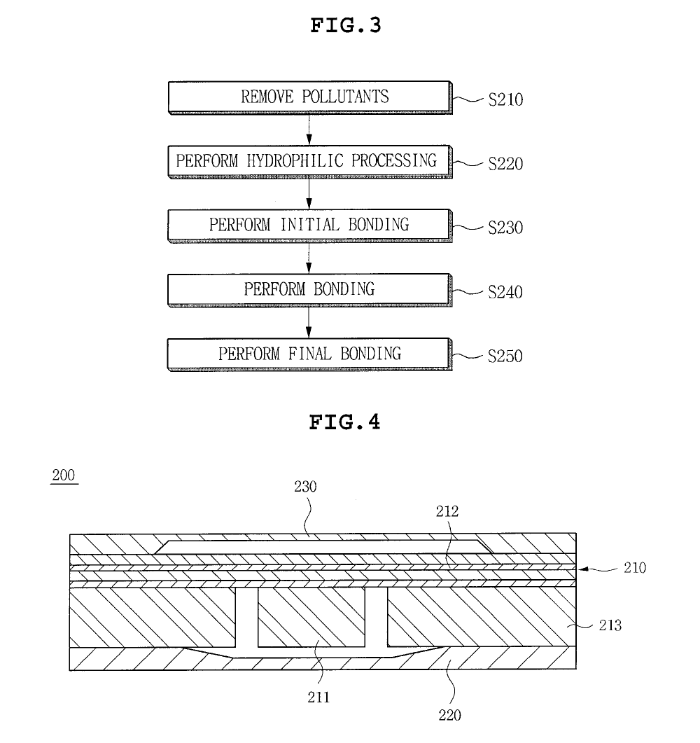

FIG. 3 is a flow chart schematically showing the silicon direct bonding step in the method of manufacturing an inertial sensor according to the preferred embodiment of the present invention. As shown, the silicon direct bonding step includes a pollutant removing step (S210), a hydrophilic processing step (S220), an initial bonding step (S230), a bonding step (S240), and a final bonding step (S250) by high-temperature heat-treatment.

In more detail, the pollutant removing step (S210) is a step of removing pollutants on the surface of the wafer.

Further, the initial bonding step (S230) performs temporary bonding only by the contact of the surface of the wafer surface without heat energy and the adhesion is determined according to wafer Bow, roughness of the surface, pollution, and hydrophilic processing, or the like. In addition, the Bow degree of the wafer has a great influence so as not to perform the initial bonding. To this end, a pressure applied at an initial bonding step may be 0.6 bar to 0.8 bar.

Further, the hydrophilic processing step (S220) may select one of a Wet method using a SPM/SC-1 solution, or the like and a plasma activation method, but the plasma activation method is more preferable than the wet method, in order to lower the heat treatment temperature of the final bonding step after bonding.

Further, the bonding step (S240) performs the pressing at normal temperature, that is, 15° C. to 400° C. or less by using a bonding agent. Further, the final bonding step (S250) performs the heat treatment at 1000° C. to 1300° C. using a furnace, preferably about 1200° C.

In addition, at the silicon direct bonding step, the most important issue is the reduction in voids, together with adhesion. The void occurs due to pollutants such as dust, or the like, trapped gas during the bonding, moisture remaining on the surface of the wafer by the hydrophilic processing or occurring by the bonding by-products, or the like. The hydrophilic processing or occurring by the bonding by-products, or the like. The pollutants are removed during the pollutant removing step before the bonding.

In addition, since the trapped gas is mainly formed by meeting several bonding waves during the bonding step, it is preferable to perform the bonding so as to generate a single bonding wave at a center or an edge of the wafer and spread the single bonding wave to the front surface of the wafer and it is easy to spread the moisture to the outside of the wafer by performing the heat treatment at a stepwise temperature step in order to reduce the voids. However, the excessive hydrophilic enhancement according to the degree and condition of the cleaning increases the residual moisture on the surface of the wafer, which increases the void after the heat treatment. Further, in order to remove the pollutants on the wafer, the final pollutant removal of the wafer manufactured before the bonding may not be omitted and the surface treatment before the bonding is necessarily performed in order to perform the hydrophilic processing for forming the bonding wave to have a limitation in weakening the hydrophilic property.

Therefore, the final bonding step (S250) may include a holding step for a predetermined time or more at normal temperature before the heat treatment. The holding step is to sufficiently diffuse the moisture occurring as a by-product during the bonding step with the residual moisture on the bonding surface of the wafer through an interface at which the final bonding is not made and to discharge the moisture to the outside of the wafer. The holding step may perform the holding for 24 hours to 48 hours.

FIG. 4 is a cross-sectional view schematically showing the inertial sensor according to the preferred embodiment of the present invention. As shown, the inertial sensor 200 further includes an upper cap 230, when comparing with the inertial sensor 100 shown in FIG. 1.

In more detail, the inertial sensor 200 includes a sensor unit 210, a lower cap 220, and an upper cap 230. Herein, the sensor unit 210 includes a mass 211, a flexible substrate part 212, and a support body 213.

Further, the upper cap 230 is to protect the electrode formed on the flexible substrate part 212 and may be made of silicon that is the same material as the flexible substrate part 212 and the support body 213 or may be made of Pyrex glass, or the like, having similar thermal expansion coefficient, and uses silicon that is the same material in consideration of workability and process capability. Further, the flexible substrate part 212 and the upper cap 230 may be bonded by a polymer and may be bonded by the silicon direct bonding according to the exemplary embodiment of the present invention.

As set forth above, the preferred embodiment of the present invention may provide the inertial sensor and the method of manufacturing the same capable of improving the convenience in manufacturing and the reliability of the sensor by coupling the sensor unit with the lower cap of the inertial sensor by the silicon direct bonding method.

Although the embodiment of the present invention has been disclosed for illustrative purposes, it will be appreciated that an inertial sensor and a method of manufacturing the same according to the invention are not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An inertial sensor, comprising:
a sensor unit including a flexible substrate part on which a driving electrode and a sensing electrode are formed, a mass displaceably mounted on the flexible substrate part, and a support body coupled with the flexible substrate part in order to support the mass in a floated state and made of silicon; and
a lower cap covering a bottom portion of the mass and made of silicon,
wherein the lower cap and the sensor unit are coupled by a silicon direct bonding method.

2. The inertial sensor as set forth in claim 1, wherein the silicon direct bonding method removes pollutants on a surface of a wafer, performs hydrophilic processing thereon, initially bonds the sensor unit and the lower cap by pressing, bonds the sensor unit and the lower cap by using a bonding agent and pressing, and finally bonds the sensor unit and the lower cap by high-temperature heat treatment.

3. The inertial sensor as set forth in claim 1, further comprising an upper cap covering a top portion of the flexible substrate part.

4. The inertial sensor as set forth in claim 3, wherein the upper cap is made of silicon, the flexible substrate part is formed of a silicon on insulator (SOI) wafer, and the upper cap and the flexible substrate part are coupled by the silicon direct bonding method.

5. A method of manufacturing an inertial sensor, the method comprising:
a sensor unit forming step forming a mass and a support body by etching a silicon on insulator (SOI) wafer;
a lower cap forming step providing a lower cap coupled with the support body so as to cover the mass of the SOI wafer;
a silicon direct bonding step coupling the lower cap with the support body of the SOI wafer; and
an electrode pattern forming step forming an electrode pattern on the top surface of the SOI wafer.

6. The method as set forth in claim 5, wherein the lower cap forming step prepares a silicon wafer and forms a cavity by etching the silicon wafer.

7. The method as set forth in claim 5, wherein the silicon direct bonding step removes pollutants on a surface of a wafer, performs hydrophilic processing thereon, initially bonds the sensor unit and the lower cap by pressing, bonds the sensor unit and the lower cap by using a bonding agent and pressing, and finally bonds the sensor unit and the lower cap by high-temperature heat treatment.

8. The method as set forth in claim 7, wherein a pressure applied during the initial bonding step is 0.6 bar to 0.8 bar.

9. The method as set forth in claim 7, wherein the hydrophilic processing step is a plasma activation method.

10. The method as set forth in claim 7, wherein the bonding step performs pressing at 15° C. to 400° C. or less using a bonding agent.

11. The method as set forth in claim 7, wherein the final bonding step performs heat treatment at 1000° C. to 1300° C. using a furnace.

12. The method as set forth in claim 7, wherein the final bonding step includes a holding step holding at normal temperature before high-temperature heat treatment.

13. The method as set forth in claim 12, wherein the holding step performs the holding for 24 hours to 48 hours.

14. The method as set forth in claim 5, wherein the electrode pattern forming step deposits an electrode material on a top surface of the device wafer and forms a driving electrode pattern and a sensing electrode pattern by pattern formation.
